(19) United States
(12) Patent Application Publication
(10) Pub. No.: US 2024/0186152 A1
(43) Pub. Date: Jun. 6, 2024

(54) CHIP PACKAGE AND METHOD INCLUDING ENCAPSULATING SPACED CHIPS BY LOCALLY CURABLE MATERIAL

(71) Applicant: Infineon Technologies AG, Neubiberg (DE)

(72) Inventors: Roslie Saini BAKAR, Melaka (MY); Hock Heng CHONG, Melaka (MY); Swee Kah LEE, Melaka (MY); Wei Wei YONG, Unterhaching (DE)

(73) Assignee: Infineon Technologies AG, Neubiberg (DE)

(21) Appl. No.: 18/388,581

(22) Filed: Nov. 10, 2023

(30) Foreign Application Priority Data
Dec. 2, 2022 (DE) 10 2022 131 934.2

(51) Int. Cl. H01L 21/56; H01L 23/31

(52) U.S. Cl. CPC H01L 21/561; H01L 21/568; H01L 23/3185

(57) ABSTRACT

A method of processing chips is disclosed. In one example, the method comprises encapsulating mutually spaced chips by an encapsulant comprising a locally curable material. The encapsulated chips with the encapsulant are separated into a plurality of encapsulated chip sections by locally curing selectively portions of the encapsulant covering at least a portion of the chips without curing other portions of the encapsulant apart from the encapsulated chip sections.

### CROSS-REFERENCE TO RELATED APPLICATION

This Utility patent application claims priority to German Patent Application No. 10 2022 131 934.2 filed Dec. 2, 2022, which is incorporated herein by reference.

### BACKGROUND OF THE INVENTION

### Field of the Invention

The present invention relates to a method of processing chips, and relates to a package.

### Description of the Related Art

Packages may be encapsulated electronic chips with electrical connects extending out of the encapsulant and being connectable to an electronic periphery. Before packaging, a semiconductor wafer is separated into a plurality of electronic chips. During and/or after separating the wafer into the separated electronic chips, the electronic chips of the wafer may be spatially expanded on an adhesive tape so that separation and picking of the individual chips is simplified.

### SUMMARY OF THE INVENTION

There may be a need to encapsulate chips efficiently.

According to an exemplary embodiment, a method of processing chips is provided, wherein the method comprises encapsulating mutually spaced chips by an encapsulant comprising a locally curable material, and separating the encapsulated chips with the encapsulant into a plurality of encapsulated chip sections by locally curing selectively portions of the encapsulant covering at least a portion of the chips without curing other portions of the encapsulant apart from the encapsulated chip sections.

According to another exemplary embodiment, a package is provided which comprises a chip, and an encapsulant encapsulating part of the chip and comprising a locally cured material and an agent for locally curing said locally cured material.

### BRIEF DESCRIPTION OF THE DRAWINGS

The accompanying drawings, which are included to provide a further understanding of exemplary embodiments of the invention and constitute a part of the specification, illustrate exemplary embodiments of the invention.

In the drawings:

FIG. 1 illustrates a cross-sectional view of a package according to an exemplary embodiment.

FIG. 2 illustrates a flowchart of a method of processing chips of a wafer according to an exemplary embodiment.

FIG. 3 to FIG. 8 show different views of structures obtained during carrying out a method of processing chips according to an exemplary embodiment.

### DETAILED DESCRIPTION OF EXEMPLARY EMBODIMENTS

There may be a need to encapsulate chips efficiently.

According to an exemplary embodiment, a method of processing chips is provided, wherein the method comprises encapsulating mutually spaced chips by an encapsulant comprising a locally curable material, and separating the encapsulated chips with the encapsulant into a plurality of encapsulated chip sections by locally curing selectively portions of the encapsulant covering at least a portion of the chips without curing other portions of the encapsulant apart from the encapsulated chip sections.

According to another exemplary embodiment, a package is provided which comprises a chip, and an encapsulant encapsulating part of the chip and comprising a locally cured material and an agent for locally curing said locally cured material.

According to an exemplary embodiment, a package manufacturing architecture includes an encapsulation of an arrangement of mutually spaced chips by covering said chips by a locally curable encapsulant, i.e. by a not yet cured encapsulant material. Thereafter, the encapsulated chips may be separated into individually encapsulated chip sections by locally curing only portions of the encapsulant covering and at least partially surrounding the chips. Advantageously, other portions of the uncured encapsulant between neighboured encapsulated chip sections will not be cured so that the corresponding encapsulant material will selectively remain uncured between the neighboured chip sections. Consequently, the uncured encapsulant material between adjacent encapsulated chip sections may remain unhardened while the encapsulant material of the encapsulated chip sections may be hardened. Thus, it may be easily possible to separate the encapsulated chip sections from each other at the intentionally mechanically weak, unstable and non-cured encapsulant portions apart from the encapsulated chip sections. This may significantly simplify a separation process compared with conventional approaches cutting or sawing through cured encapsulant material. In particular, this may also render a cumbersome pick and place process of individually picking singulated chips dispensable, since the described separation process may allow to easily collect separated encapsulated chip sections in a container or the like, for example when the separated encapsulated chip sections fall down under the influence of gravity while self-separating each other at the selectively uncured and therefore mechanically weak encapsulation interfaces in between. Hence, it may be possible to cure only encapsulant material around the chips, but not between the chips. This may render chip sawing and a pick and place process unnecessary.

Advantageously, an obtained encapsulated chip section may be directly used as readily manufactured package (or may be optionally post-processed). In this way, also a very simple package may be manufactured highly efficiently, in particular being free of a chip carrier and requiring no additional encapsulation process. The encapsulant of such a package may still comprise an agent, such as a photoinitiator, used for locally curing the locally cured material. Descriptively speaking, such an agent may be a fingerprint of the above described manufacturing process.

### Description of Further Exemplary Embodiments

In the following, further exemplary embodiments of the method and the package will be explained.

In the context of the present application, the term “chip” (or electronic chip or electronic component) may particularly denote a naked die, i.e. a non-packaged (for instance non-molded) chip made of a processed semiconductor, for instance a singulated piece of a semiconductor wafer. A semiconductor chip may however also be an already packaged (for instance molded or laminated) die. One or more integrated circuit elements (such as a MEMS, a diode, a transistor, etc.) may be formed within the semiconductor chip. Such a semiconductor chip may be equipped with a metallization, in particular with one or more pads. The chip may be embodied for instance as power semiconductor chip, active electronic device (such as a transistor), passive electronic device (such as a capacitance or an inductance or an ohmic resistance), sensor (such as a microphone, a light sensor or a gas sensor), actuator (for instance a loudspeaker), or microelectromechanical system (MEMS). Semiconductor chips implemented according to exemplary embodiments may be formed for example in silicon technology, gallium nitride technology, silicon carbide technology, etc.

In the context of the present application, the term “mutually spaced chips” may particularly denote an arrangement of chips (for instance arranged in rows and columns) being positioned laterally spaced from each other so that sidewalls of adjacent chips are laterally displaced. The mutual spacing between the chips may be along two perpendicular directions within a common plane, or only along one direction.

In the context of the present application, the term “encapsulant” may particularly denote a substantially electrically insulating material configured for surrounding at least part of a chip to provide mechanical protection, electrical insulation, and optionally a contribution to heat removal during operation. In particular, said encapsulant may comprise a resin. For instance, the encapsulant may comprise a matrix of selectively curable material, and optionally filler particles embedded therein. For instance, filler particles may be used to adjust the properties of the encapsulant. It is also possible that the encapsulant is a selectively curable molding, potting or casting compound. For example, the encapsulant may be formed based on a photo imaging tape or an epoxy paste.

In the context of the present application, the term “locally curable material” may particularly denote an encapsulant material which is capable to be processed so that only a local portion thereof becomes cured and thereby hardened, whereas a remaining portion thereof may remain uncured and unhardened. For example, locally curing such an encapsulant material may be accomplished by the spatially dependent application of a curing trigger, such as the local application of heat or the local irradiation with electromagnetic radiation (such as a laser beam or a beam of ultraviolet radiation).

In the context of the present application, the term “locally cured material” may particularly denote encapsulant material which has already been cured by the local application of a curing trigger such as electromagnetic radiation or heat. For example, locally cured material may already have completed a cross-linking or polymerization reaction of resin material thereof. An agent for locally curing the previously curable and now cured material may still be present in the locally cured material.

In the context of the present application, the term “locally curing” may particularly denote the process of executing curing of curable encapsulant material selectively and only in a partial region thereof. The spatial region of locally curing an encapsulant may be selected by the locally dependent application of a curing trigger to only part of the encapsulant. Such a curing trigger may act on a dedicated portion of the encapsulant material only and may trigger curing thereof only where the encapsulant material is impacted by the curing trigger.

In the context of the present application, the term “agent for locally curing locally curable encapsulant material” may particularly denote a chemical substance, for instance an additive of a resin-based encapsulant, which, when impacted by a curing trigger such as ultraviolet radiation (or heat or electromagnetic radiation of another appropriate wavelength range), promotes, catalyses or carries out an encapsulant curing process. In particular, said agent may be a photoinitiator initiating a photo-based curing of the encapsulant, in particular resin thereof. For instance, such an agent may start or promote polymerization or cross-linking of previously uncured resin, such as epoxy resin. For example, a photoinitiator may be a molecule that creates reactive species (for example free radicals, cations or anions) when exposed to radiation (in particular ultraviolet light or visible light). Synthetic photoinitiators may be used in photopolymers, wherein the latter may form at least part of the resin of the encapsulant. A photopolymer can be denoted as a light-activated resin which may be a polymer that changes its properties when exposed to light, preferably in the ultraviolet or visible region of the electromagnetic spectrum. These changes may lead to a hardening of the material as a result of cross-linking when exposed to light. A photoinitiator can create reactive species by different pathways including photodissociation and electron transfer.

In the context of the present application, the term “encapsulated chip section” may particularly denote a unit or member comprising one or more chips encapsulated at least partially by an encapsulant. For example, such an encapsulated chip section may be directly used as a readily manufactured package, or may be further processed for forming a more complex package.

In the context of the present application, the term “package” may particularly denote an electronic member which may comprise one or more chips which may be encapsulated at least partially by an encapsulant. For example, many packages may be manufactured simultaneously as a batch before being separated into individual packages. A package may be formed as previously mentioned encapsulated chip section, or may comprise one or more additional elements, such as a carrier and/or a further encapsulant.

In an embodiment, the locally curing comprises selectively irradiating, in particular using a mask, said portions of the encapsulant by irradiation with curing electromagnetic radiation, in particular ultraviolet (UV) electromagnetic radiation, without irradiating said other portions of the encapsulant with said curing electromagnetic radiation. Advantageously, an irradiation pattern according to which only a portion of uncured encapsulant material applied to the mutually spaced chips may precisely define which portions of the uncured encapsulant will be cured and which not. This selective irradiation may be in accordance with a mask design which defines irradiation transparent and irradiation intransparent sections. As an alternative to the provision of a mask, it is also possible to provide a spatially confined electromagnetic radiation beam (for instance a UV laser beam) moving only over those portions of an arrangement of chips which shall be selectively cured. Only those regions of encapsulant will then be cured and therefore hardened which are impacted by the curing radiation beam. Curing of encapsulant material may be accomplished by UV exposure.

In an embodiment, the method comprises washing away the uncured other portions of the encapsulant apart from the encapsulated chip sections. More specifically, the uncured area may be washed away, for example by a developing agent. A suitable developing agent may be an organic solvent, such as propylene carbonate, gamma butyrolactone, etc.

In an embodiment, the encapsulant may be formed by attaching a solid encapsulant layer to the mutually spaced chips, or by coating the mutually spaced chips by an encapsulant liquid. For example, a solid encapsulant layer may be formed by one or more foils or films of curable encapsulant material being attached, preferably laminated, on the arrangement of mutually spaced chips. Care should be taken that such a solid encapsulant layer is not entirely cured by the application process. As an alternative, the cured encapsulant layer may also be attached by coating the arrangement of mutually chips with a flowable, vicious or liquid uncured encapsulant. For instance, the latter may be applied by spin coating. A spatially dependent curing selectively of sections of the encapsulant material covering the chips may be carried out preferably after the having applied the layer of encapsulant material to the chips. However, it may also be possible to execute curing partially or entirely already during the application process, for instance by applying curing-triggering heat and/or mechanical pressure selectively only to chip covering regions of the uncured encapsulant layer while maintaining intermediate regions of the encapsulant uncured.

In an embodiment, the method comprises separating the encapsulated chip sections from each other at the uncured other portions of the encapsulant. When separating encapsulated chip sections, in particular serving as readily manufactured packages, at unhardened and therefore mechanically instable or soft intermediate portions of the encapsulant between hardened chip covering portions of the encapsulant, the encapsulation process can be carried out with very low separation forces between adjacent encapsulated chip sections. Time-consuming separation processes for separating packages, such as sawing or laser dicing through hardened encapsulant, can thus be advantageously omitted. In contrast to this, the cured encapsulated chip sections may be separated from each other by simply pulling or shaking the encapsulated chip sections, or preferably automatically merely under the influence of gravity. This may significantly simplify and accelerate a package singulation process.

In an embodiment, the method comprises expanding an expansion tape on which the chips of a common wafer are arranged to thereby mutually space the chips. In the context of the present application, the term “wafer” may particularly denote a semiconductor substrate which has been processed to form a plurality of integrated circuit elements in an active region of the wafer and which may be, when being expanded according to an exemplary embodiment, already singulated into a plurality of separate chips. For example, a wafer may have a disk shape and may comprise a matrix-like arrangement of chips in rows and columns. It is possible that a wafer has a circular geometry or a polygonal geometry (such as a rectangular geometry or a triangular geometry). By expansion of a wafer on a stretchable expansion tape, the chips may be spaced from each other preferably along the entire perimeter thereof. This may form a proper basis for the subsequent application of an uncured encapsulant layer on all the mutually spaced chips in common.

In an embodiment, the method comprises encapsulating the chips on the expanded expansion tape by the encapsulant. For example, an encapsulant layer may be applied to all chips while the mutually expanded chips are still arranged on the expanded expansion tape functioning also as a bottom-sided support during encapsulation. This may further simplify the manufacturing process and increase its yield.

In an embodiment, the method comprises expanding the expansion tape so that the chips of the wafer are mutually spaced in two perpendicular spatial directions of a plane of the expansion tape. Consequently, for example cuboid-shaped chips may be separated from neighbouring chips along all four side walls. This may enable a fully circumferential encapsulation of the chips. For example, the expansion tape may be expanded so that the chips of the wafer are mutually spaced by a distance in a range from 20 μm to 150 μm. This leads to the manufacturability of encapsulated chip sections with reliable side wall-coated chips while also ensuring a well-defined separation of the chips and of the encapsulated chip sections by uncured intermediate encapsulant portions.

In an embodiment, the method comprises mounting the wafer, when still being integral, on a separation tape, and thereafter separating the chips from the previously integral wafer. When being arranged on the separation tape, the individual chips may be singulated from the wafer compound for example by mechanically dicing or by laser dicing. After that, adjacent chips may be still arranged side-by-side and in particular with mutual contact.

In an embodiment, the method comprises connecting the separated chips with said expansion tape, and thereafter removing said separation tape. While the separation tape may be optimized as a robust support for wafer dicing, the expansion tape may have stretchable properties for mutually spacing the chips. Thus, after wafer dicing and before expansion, a tape exchange may be carried out.

In an embodiment, the method comprises attaching a release layer to the encapsulant. A release layer may be a layer made of material which may hold (for instance in an adhesive way) the chips before triggering release of the chips from the release layer. Such a trigger for releasing the chips from the release layer may be a modification of the ambient conditions for converting the release layer from a chip holding configuration into a chip releasing configuration. In particular, triggering release of the chips from the release layer may be accomplished by supplying heat which converts the release layer from an adhesive to a non-adhesive or less adhesive configuration.

In an embodiment, the method comprises releasing the encapsulated chip sections from the release layer. Before releasing the encapsulated chip sections from the release layer, an expansion tape, which may have been used earlier for expanding chips separated from a wafer compound, may be removed from the encapsulated chips. Selectively releasing the encapsulated chip sections from the release layer may then complete the chip encapsulation and singulation process.

In an embodiment, the method comprises treating the release layer and/or the encapsulant, in particular by supplying heat, for promoting release of the encapsulated chip sections from the release layer. Before releasing the encapsulated chip sections from the release layer, the release layer may exert an adhesive holding force to the encapsulated sections. By heating the release layer, said holding force may be significantly reduced or even eliminated so that the encapsulated chip sections may be easily removed from the release layer. In other embodiments, rendering the release layer non-adhesive may be accomplished by taking another measure than heating, for instance by irradiation with corresponding electromagnetic radiation.

In an embodiment, the method comprises collecting the encapsulated chip sections released automatically, in particular falling down by the force of gravity, from the release layer. In such a configuration, the encapsulated chip sections attached to the initially adhesive release layer may be located at a bottom side of the release layer. When the encapsulated chip sections are arranged face-down on the release layer, a triggered conversion of the release layer from an adhesive configuration into a non-adhesive or low-adhesive configuration will lead to an automatic release of the encapsulated chip sections from the no more strongly adhesive release layer so that the vanishing holding force in combination with gravity will force the encapsulated chip sections to leave the release layer and fall downwardly. Hence, a very simple way of separating and collecting the encapsulated chip sections or packages may be provided.

Consequently, it may be possible to release all encapsulated chip sections in a common process under the force of gravity by reducing an attaching force of the release layer. As already mentioned, converting the release layer from an adhesive to a non-adhesive configuration may be accomplished by supplying heat. Depending on the properties and configuration of the release layer, also another trigger for loss of a holding force may be used, for instance cooling, irradiation with electromagnetic radiation causing a loss of a holding force, etc.

In an embodiment, said locally cured material of the package is obtained from locally curing a locally curable material by irradiation with electromagnetic radiation, in particular ultraviolet electromagnetic radiation. A corresponding agent which has promoted said curing may still be present in the final encapsulant of the package. In particular, said locally cured material may comprise a cured polymer and a photoinitiator as said agent. Said photoinitiator may be configured for promoting curing of an initially uncured polymer to thereby form said cured polymer when being irradiated with electromagnetic radiation, in particular ultraviolet electromagnetic radiation.

In an embodiment, said encapsulant comprises a photo imaging polymer. A photo imaging polymer or photopolymer can be denoted as a light-activated resin. Such a resin may be a polymer that changes its properties when exposed to light, preferably in the ultraviolet or visible region of the electromagnetic spectrum. Such a photo imaging polymer may be converted from a non-cured condition into a cured condition by electromagnetic radiation and an appropriate agent for locally curing a photo imaging polymer. Changes in structural and chemical properties of a photo imaging polymer can be induced by chromophores that a polymer subunit already possesses, and/or externally by addition of photosensitive molecules or other appropriate agents. A photo imaging polymer may comprise a mixture of multifunctional monomers and oligomers depending on intended functional properties of the encapsulant. Photopolymers may undergo curing by cross-linking oligomers upon exposure to light of an appropriate wavelength, thereby forming a network polymer. More specifically, the result of photo-curing may be the formation of a thermoset network of polymers.

In an embodiment, said encapsulant encapsulates sidewalls and only one main surface of the chip. In particular, all four side walls of a respective chip may be fully covered by encapsulant material. In addition, one of two opposing main surfaces may be covered by encapsulant material as well. Only one main surface of the chip may then remain exposed beyond the encapsulant. More specifically, five of six surfaces of the chip may be fully covered by encapsulant material. The main surface of the chip which is not covered by the encapsulant material may comprise one or more exposed chip pads which can be used for electrically connecting the package with an electronic periphery. For example, the encapsulated chip section or package may be mounted on a mounting base, such as a printed circuit board, so that the one more exposed pads may be electrically coupled with one or more electrically conductive pads and/or wiring elements of the mounting base.

In an embodiment, a thickness of said encapsulant on at least part of the sidewalls and/or on the encapsulated main surface of the chip is in a range from 10 μm to 75 μm. Consequently, highly compact packages may be provided which may nevertheless have a reliable side wall coverage with encapsulant material. This combines a compact design with a high electrical and mechanical reliability.

In an embodiment, the chip comprises at least one of the group consisting of a diode chip, and a passive electronic component. When embodied as a diode chip, a diode may be monolithically integrated in a semiconductor substrate. A passive electronic component may for example comprise a capacitance, an inductance or an ohmic resistor manufactured in chip technology.

In an embodiment, the chip comprises at least one pad exposed at a main surface of the chip which is exposed with respect to the encapsulant. For example, one or more chip pads may be formed only on one of two opposing main surfaces of the chip for connection of the package with an electronic periphery. For instance, such a chip may be oriented face-down with the at least one chip pad being exposed at a bottom side of the package. Alternatively, a chip may have pads on both opposing main surfaces (for instance in a semiconductor device with vertical current flow, for instance in a field effect transistor chip). In such a configuration, both opposing main surfaces of the chip may be free of encapsulant material.

In an embodiment, the chips are power semiconductor chips. Such a power semiconductor chip may have integrated therein one or multiple integrated circuit elements such as transistors (for instance field effect transistors like metal oxide semiconductor field effect transistors and/or bipolar transistors such as insulated gate bipolar transistors) and/or diodes. Exemplary applications which can be provided by such integrated circuit elements are switching purposes. For example, such another integrated circuit element of a power semiconductor device may be integrated in a half-bridge or a full bridge. Exemplary applications are automotive applications.

The one or more chips may comprise at least one of the group consisting of a diode, and a transistor, more particularly an insulated gate bipolar transistor. For instance, the one or more electronic chips may be used as semiconductor chips for power applications for instance in the automotive field. In an embodiment, at least one semiconductor chip may comprise a logic IC or a semiconductor chip for RF power applications. In one embodiment, the semiconductor chip(s) may be used as one or more sensors or actuators in microelectromechanical systems (MEMS), for example as pressure sensors or acceleration sensors, as a microphone, as a loudspeaker, etc.

As substrate or wafer for the semiconductor chips, a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages of the present invention will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

In conventional packaging technology, it may be necessary to pick up dies individually using die bonders. Such a conventional approach may suffer from limited throughput. Furthermore, without protection, chipping at edges of a bare silicon die may occur.

According to an exemplary embodiment, a manufacturing process comprises encapsulating mutually spaced chips by an encapsulant having a locally curable material. After that, the encapsulant-chips body may then be separated in a very simple manner into package-type encapsulated chip sections. Advantageously, this may be accomplished by executing a local curing process which only locally cures selectively only portions of the encapsulant around the respective chips (or around respective chip groups). Locally cured encapsulant around the chips may reliably protect the chips against mechanical impact and may electrically decouple the chips from an environment in a reliable way. In contrast to the curing of encapsulant portions directly next to the chips, curing other portions of the encapsulant apart from the encapsulated chip sections may be intentionally omitted so that the corresponding intermediate encapsulant portions between packages may remain uncured. While the selectively cured portions around the chips may be hardened by curing, the non-cured intermediate sections of the encapsulant may remain unhardened. Therefore, separation of cured and hardened encapsulated chip sections from each other may be executed at the uncured and unhardened intermediate encapsulant sections in between the encapsulated chip sections. Advantageously, this may be accomplished without sawing through hardened encapsulant material and thus in a simple and quick way. Moreover, a conventionally cumbersome pick and place process for picking individual chips and place them at a destination may become dispensable. Since the hardened encapsulated chip sections have soft or unhardened intermediate encapsulant material in between, separation can be accomplished by a low separation force or even automatically by triggering the encapsulated chip portions to fall downward separately from each other, for instance under the influence of gravity.

More specifically, exemplary embodiments enable high throughput packaging by expanding chips of a diced wafer followed by the application of a photo imaging polymer-type encapsulant. By selectively photo curing only portions of said encapsulant preform, encapsulated chip sections may be defined being separated by only weakly connected non-cured and therefore mechanically unstable encapsulant portions. Separation of the individual encapsulated chip sections may be carried out with low effort and low force at the mechanically weak non-cured and therefore unhardened portions of the photo imaging polymer-type encapsulant.

Furthermore, an exemplary embodiment may use an expandable foil to enable chip edge spacing within a horizontal plane. In other words, this may ensure sufficient distancing of neighboring chips after wafer dicing or etching. Advantageously, a layer of encapsulant may be provided in form of a photo polymer sheet as top and side protection layer for the bare dice. Thereafter, a mask may be used to remove an unwanted portion of the polymer sheet to separate the encapsulated dice or chips from each other. More specifically, this may be accomplished by irradiating only encapsulant portions around the chips with ultraviolet (UV) radiation for curing, while a mask will prevent UV exposure of encapsulant portions between adjacent encapsulated chips. Consequently, non-irradiated and therefore non-cured and unhardened encapsulant portions may be easily removed which separates the encapsulated chip sections. Said encapsulated chip sections, being already separated or being only weakly connected by uncured encapsulant portions, may then be transferred to a heat release laminate tape for preparing a bulk release of the separated and encapsulated dies. Upon heating the release laminate side, the encapsulated chip sections will be released from the laminate tape altogether. The released encapsulated chip sections, which may already be used as final packages, may then be collected for further use.

Thus, the selectively cured encapsulant may be used for bare silicon die protection. In such a way, a high throughput packaging process can be provided which can increase or even maximize a final bulk packing efficiency. In particular, this may make it possible to enable bulk packaging in particular for passive components. Exemplary embodiments may provide an ultra-small bare die protection using a simple polymer sheet which can then be selectively cured in accordance with a predefined spatial curing pattern.

Thus, an exemplary embodiment provides an encapsulation architecture using a photo imaging polymer sheet for protecting bare silicon dies. Simultaneously, an encapsulation and package separation process may be rendered highly efficiently.

In one embodiment, a wafer may be arranged on an expandable foil to be extended for chip spacing. The expandable foil may be stretched for edge distancing of the chips after wafer dicing or etching. A photo imaging polymer sheet may be attached as pre-form of an encapsulant. A photoinitiator agent may be inserted in the encapsulant. The photo imaging polymer sheet may encapsulate the chips separated from the wafer. A mask may be used to separate the encapsulated dice without dicing. The separated dies may be bulk packaged. Advantageously, UV separation may be accomplished without the need of mechanically sawing through a hardened encapsulant. Due to the described batch process, no individual pick up of encapsulated chips may be necessary. The mentioned concept may enable efficient bulk packaging.

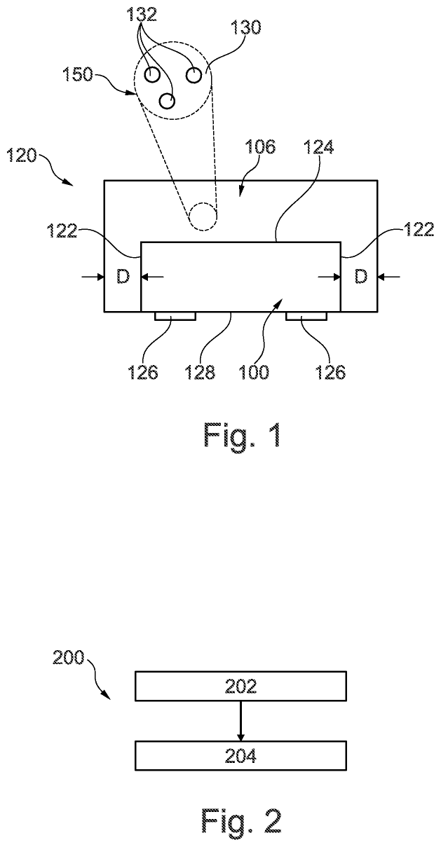

FIG. 1 illustrates a cross-sectional view of a package 120 according to an exemplary embodiment.

The package 120 according to FIG. 1 comprises a chip 100, such as a semiconductor chip (for instance a passive component having an integrated diode). Furthermore, an encapsulant 106 is provided which encapsulates part of the chip 100. The encapsulant 100 comprises a locally cured material (for instance polymerized epoxy resin) and an agent (such as a photoinitiator) for locally curing said locally cured material during a manufacturing process (for instance when being irradiated by appropriate electromagnetic radiation, such as UV light).

As shown in a detail 150, encapsulant 106 may for example comprise a cured polymer 130 as the locally cured material, and a photoinitiator 132 as the agent for locally curing said locally cured material.

Said locally cured material may be obtained from locally curing a locally curable material (such as not yet or not yet fully polymerized epoxy resin) by irradiation with electromagnetic radiation, such as ultraviolet electromagnetic radiation. The above-mentioned photoinitiator 132 may be configured for promoting curing of an initially uncured polymer (such as the above mentioned not yet polymerized epoxy resin) to thereby form said cured polymer 130 when being irradiated with ultraviolet electromagnetic radiation. Hence, said encapsulant 106 may be manufactured using a photo imaging polymer.

Again referring to FIG. 1, said encapsulant 106 may encapsulate sidewalls 122 and only one main surface 124 of the chip 100. As shown as well, the chip 100 may comprise one or more pads 126 exposed at a main surface 128 of the chip 100 which is exposed with respect to the encapsulant 106. Thus, main surface 124 may be encapsulated by the encapsulant 106, whereas the opposing other main surface 128 is exposed beyond the encapsulant 108 for enabling an electric connection of the encapsulated chip 100 to an electronic periphery (not shown in FIG. 1). For example, the package 120 shown in FIG. 1 may be mounted on a mounting base (not shown), such as a printed circuit board. Pads on the surface of such a mounting base may be connected to the chip pads 126.

For example, a thickness D of said encapsulant 106 on the sidewalls 122 may be in a range from 10 μm to 75 μm.

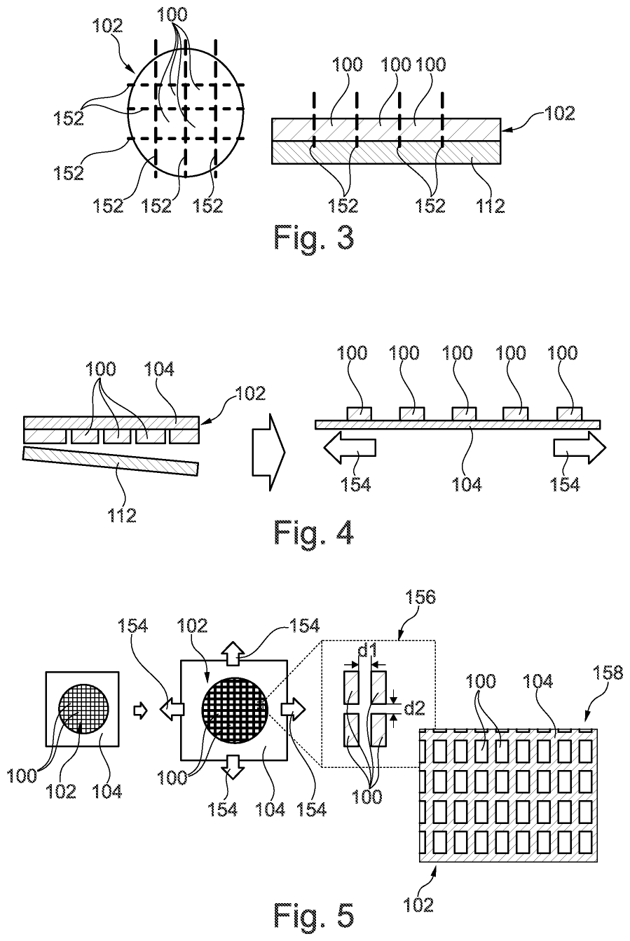

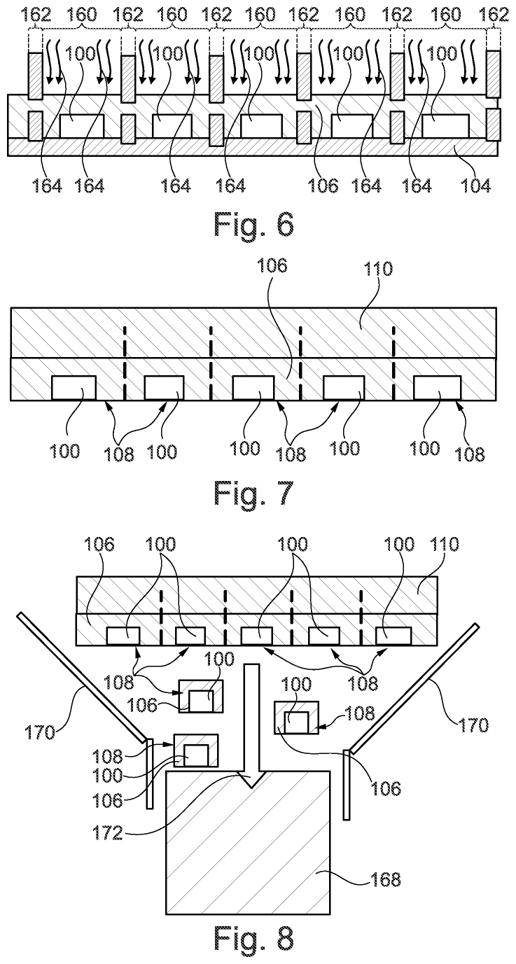

FIG. 2 illustrates a flowchart 200 of a method of processing chips 100 of a wafer (see reference sign 102 in FIG. 3) according to an exemplary embodiment. The reference signs used for the following description of said manufacturing method also relate to the embodiment of FIG. 3 to FIG. 8.

Referring to a block 202, the method comprises encapsulating mutually spaced chips 100 by an encapsulant 106 comprising a locally curable material (see FIG. 6 for further details).

Referring to a block 204, the method furthermore comprises separating the encapsulated chips 100 with the encapsulant 106 into a plurality of encapsulated chip sections 108 by locally curing selectively portions of the encapsulant 106 covering at least a portion of the chips 100 without curing other portions of the encapsulant 106 apart from the encapsulated chip sections 108 (see FIG. 6 to FIG. 8 for further details).

FIG. 3 to FIG. 8 show different views of structures obtained during carrying out a method of processing chips 100 according to an exemplary embodiment.

FIG. 3 shows a plan view and a cross-sectional view of a wafer 102 which initially comprises a plurality of integrally connected chips 100. For example, wafer 102 may be a silicon wafer comprising a plurality of portions defining the chips 100. For instance, each of the initially still integrally connected chips 100 has at least one monolithically integrated circuit element, for example an integrated diode (not shown).

As can be seen in the cross-sectional view of FIG. 3, the wafer 102, when still being integral, may be mounted on a separation tape 112. Thereafter, the individual chips 100 may be separated from the previously integral wafer 102 by wafer dicing. For instance, wafer dicing may be accomplished by cutting or sawing wafer 102 along separation lines 152 which may extend along two perpendicular directions through wafer 102. It is also possible to separate the chips 100 from the wafer 102 by etching or laser processing.

To put it shortly, wafer 102 may be mounted on separation tape 112 (which may be later removed from the individual chips 100, for example by irradiation with ultraviolet light) and may then be separated into the chips 100 for instance by wafer dicing or etching.

Referring to FIG. 4, the separated chips 100 may then be connected to an expansion tape 104 which can be attached to the chips 100 on a main surface opposing another main surface arranged on the separation tape 112. While the separation tape 112 may be configured for supporting the wafer 102 and the chips 100 during the chip separation process described above referring to FIG. 3, the expansion tape 104 may be made of stretchable material which can be used for separating adjacent chips 100 within a horizontal plane. After having connected the expansion tape 104 to the chips 100, said separation tape 112 may be removed, as shown on the left-hand side of FIG. 4. Thus, the left-hand side of FIG. 4 illustrates a transfer of chip connection with separation tape 112 to chip connection with expansion tape 104.

Now referring to the right-hand side of FIG. 4, the expansion tape 104 on which the chips 100 of common wafer 102 are arranged may then be expanded to thereby mutually space the chips 100 attached thereon. The expansion forces exerted to the expansion tape 104 and to the chips 100 during chip expansion are indicated by reference sign 154 in FIG. 4. The expansion process may be executed simultaneously or sequentially in two orthogonal directions within a horizontal plane, see also FIG. 5.

Referring now specifically to FIG. 5, the expansion process executed according to FIG. 4 will be explained in further detail.

The plan view on the left-hand side of FIG. 5 shows a circular wafer 102 (for instance having a diameter of 8 inch) mounted on a square-shaped expansion tape 104 (for example having a length and width of 300 mm).

The further plan view of FIG. 5 illustrated with reference signs 154 shows expansion of the expansion tape 104 so that the chips 100 of the wafer 102 are mutually spaced in two perpendicular spatial directions of a plane of the expansion tape 104, i.e. within the paper plane of FIG. 5.

As shown in a detail 156, the expansion of the expansion tape 104 may be carried out so that the chips 100 of the wafer 102 are mutually spaced by a distance d1 in horizontal direction and by a distance d2 in vertical direction. Both d1 and d2 may be in a range from 20 μm to 150 μm. For instance, when a respective chip 100 has dimensions of 0.4 mm×0.2 mm, the distances d1 and d2 may be each 150 μm.

A two-dimensional arrangement of the obtained chips 100 is shown by reference sign 158.

For chip expansion, the chips 100 may thus be transferred to the expansion tape 104. Thereafter, the expansion tape 100 with the chips 100 thereon may be expanded in two orthogonal directions. Chip-to-chip distances d1, d2 may be measured, for instance by a CNC (computerized numerical control) vision measuring system.

Referring to FIG. 6, a layer of encapsulant 106 may then be attached to the mutually spaced chips 100 on the expansion tape 104. In particular, the layer of encapsulant 106 may be attached to chips 100 and expansion tape 104 while the latter is still in an expanded state (i.e. still under tension) and the chips 100 are mutually spaced by the expansion tape 104.

For example, the layer of encapsulant 106 may be a film or foil of uncured encapsulant material being laminated as a solid layer on the chips 100. When applying heat and/or mechanical pressure to the solid layer of encapsulant 106 during lamination, care should be taken that at least part of, preferably the entire, curable material of the encapsulant 106 remains uncured at the end of the lamination process. As an alternative to the application of said encapsulant 106 by attaching a solid encapsulant layer to the mutually spaced chips 100, it may also be possible to apply the encapsulant 106 by coating the mutually spaced chips 100 and the expansion foil 104 by an encapsulant 106 in a flowable, preferably liquid or viscous, phase. For instance, applying a flowable encapsulant 106 may be accomplished by spin coating.

As already mentioned, after encapsulating the mutually spaced chips 100 by encapsulant 106, the latter should still comprise a locally curable material. This may ensure that following application of the uncured encapsulant 106, specific regions, positions or locations thereof may be selectively cured and thereby hardened, whereas one or more other specific regions, positions or locations thereof may remain selectively uncured and consequently unhardened. Preferably, the encapsulant 106 comprises a photo imaging polymer which can be selectively cured in a spatially dependent way by irradiating the photo imaging polymer with appropriate electromagnetic radiation, such as UV light.

Still referring to FIG. 6, selected curing portions 160 of the encapsulant 106 may then be selectively cured, whereas non-curing portions 162 of the encapsulant 106 in between may remain intentionally uncured. This may be done by selectively irradiating only the curing portions 160 of the encapsulant 106 with curing electromagnetic radiation 164, whereas no curing electromagnetic radiation 164 is irradiated onto the non-curing portions 162. For example, this may be defined by an appropriate mask or by guiding an electromagnetic radiation source generating the curing electromagnetic radiation 164 along a predefined trajectory along the encapsulant 106 and covering only part of the surface thereof during irradiation. For example, the curing electromagnetic radiation 164 may be ultraviolet light.

Hence, the local curing process may comprise selectively irradiating said curing portions 160 of the encapsulant 106 by irradiation with curing electromagnetic radiation 164, without irradiating said other non-curing portions 162 of the encapsulant 106 with said curing electromagnetic radiation 164. Only irradiated and thereby cured portions of the encapsulant 106 will be hardened.

As shown, the process of applying the spatially dependent selective curing only to curing portions 160, but not to non-curing portions 162, of the encapsulant 106 may be carried out on the chips 100 and the encapsulant 106 being arranged on the expanded expansion tape 104. The expansion tape 104 may remain intact during the described selective curing process which may be only accomplished by UV radiation. Due to the selective curing process, the curing portions 160 each surrounding a respective chip 100 may form a solid hardened cured encapsulant 106. The non-curing portions 162 in between may remain unhardened. Consequently, separation of individual encapsulated chip sections 108 (see FIG. 7) may be easily possible at the unhardened non-curing portions 162 without the need of mechanically sawing. In other words, separation regions between encapsulated chip sections 108 may be defined in the encapsulant 106 where the latter is not cured.

Hence, according to FIG. 6, the encapsulated chips 100 with the encapsulant 106 are separated into a plurality of encapsulated chip sections 108 by locally curing selectively curing portions 160 of the encapsulant 106 covering part of the chips 100 without curing the other non-curing portions 162 of the encapsulant 106 apart from the encapsulated chip sections 108, more specifically between adjacent encapsulated chip sections 108.

As shown in FIG. 7, a release layer 110 may then be attached, preferably by lamination, to the main surface of the encapsulant 106 being exposed according to FIG. 6, i.e. facing away from expansion tape 104. Thereafter, the expansion tape 104 may be removed.

In the configuration of FIG. 7, the laminated release layer 110 may adhere to the encapsulant 106 and thereby holds the encapsulated chip sections 108 being separated from each other by the mechanically weak non-curing portions 162 of encapsulant 106.

When applying heat to the illustrated and described configuration, the release layer 110 may be converted into a non-adhesive configuration and is then no longer capable of holding the encapsulated chip sections 108 thereon. Thereby, the encapsulated chip sections 108 may be released from the release layer 110 and may fall downwardly under the force of gravity. The encapsulated chip sections 108 may be separated at the mechanically weak uncured or non-curing portions 162 of the encapsulant 106 where the latter has not been hardened. To put it shortly, the encapsulated chip sections 108 are separated at the uncured non-curing portions 162 of the encapsulant 106 without mechanically sawing through hardened encapsulant material and thus in a very simple way. For example, uncured non-curing portions 162 of the encapsulant 106 may be washed away by a developing agent, such as propylene carbonate, gamma butyrolactone, etc.

Referring to FIG. 8, the latter mentioned process will be explained in further detail:

As mentioned, the described manufacturing method comprises releasing the encapsulated chip sections 108 from the release layer 110 by heat. Said heat will promote release of the encapsulated chip sections 108 from the release layer 110 which may become non-adhesive when heated. Consequently, it may be possible to collect the encapsulated chip sections 108 released automatically by falling down by the force of gravity from the release layer 110. This is indicated by reference sign 172 in FIG. 8.

Consequently, the encapsulated chip sections 108 may be collected in a container 168, such as a box. Optionally, a guiding structure 170 may support the collection process and may promote collection of the released encapsulated chip sections 108 in container 168. The guiding structure 170 may be embodied, for example, as a funnel or a cone-shaped structure.

Advantageously, the release process triggered for all encapsulated chip sections 108 in common may lead to a batch or bulk release of all encapsulated chip sections 108 in a common process. All encapsulated chip sections 108 (being already previously laterally only weakly connected by the non-curing portions 162 of the encapsulant 106 and being now also horizontally only weakly connected to the heated release layer 110) fall downward under the force of gravity. The mentioned release process is triggered by reducing an attaching force of the release layer 110 by supplying heat.

The collected encapsulated chip sections 108 may be used as readily manufactured packages 120. Each encapsulated chip section 108 may have a chip 100 (such as a diode chip) being encapsulated along five walls thereof by encapsulant 106 and being exposed at pads 126, not shown in FIG. 8, at its sixth wall. Thus, the manufactured package-type encapsulated chip sections 108 may be properly protected and electrically insulated by the encapsulant 106 while being nevertheless electrically accessible to an electronic periphery. Advantageously, a bulk packaging process may be made possible without the need of taping. Moreover, a pick and place process for individually removing chips 100 from a support may be dispensable as well.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A method of processing chips, the method comprising:
encapsulating mutually spaced chips by an encapsulant comprising a locally curable material; and
separating the encapsulated chips with the encapsulant into a plurality of encapsulated chip sections by locally curing selectively portions of the encapsulant covering at least a portion of the chips without curing other portions of the encapsulant apart from the encapsulated chip sections.

2. The method according to claim 1, wherein the locally curing comprises selectively irradiating, in particular using a mask, said portions of the encapsulant by irradiation with curing electromagnetic radiation, in particular ultraviolet electromagnetic radiation, without irradiating said other portions of the encapsulant with said curing electromagnetic radiation.

3. The method according to claim 1, wherein the method comprises applying said encapsulant by attaching a solid encapsulant layer to the mutually spaced chips, or by coating the mutually spaced chips by an encapsulant liquid.

4. The method according to claim 1, wherein the method comprises separating the encapsulated chip sections at the uncured other portions of the encapsulant.

5. The method according to claim 1, wherein the method comprises expanding an expansion tape on which the chips of a common wafer are arranged to thereby mutually space the chips.

6. The method according to claim 5, comprising at least one of the following features:
wherein the method comprises encapsulating the chips on the expanded expansion tape by the encapsulant; and
wherein the method comprises expanding the expansion tape so that the chips of the wafer are mutually spaced in two perpendicular spatial directions of a plane of the expansion tape, wherein in particular the method comprises expanding the expansion tape so that the chips of the wafer are mutually spaced by a distance in a range from 20 μm to 150 μm.

7. The method according to claim 5, wherein the method comprises mounting the wafer, when still being integral, on a separation tape, and thereafter separating the chips from the previously integral wafer.

8. The method according to claim 7, wherein the method comprises connecting the separated chips with said expansion tape, and thereafter removing said separation tape.

9. The method according to claim 1, wherein the method comprises attaching a release layer to the encapsulant.

10. The method according to claim 9, wherein the method comprises releasing the encapsulated chip sections from the release layer.

11. The method according to claim 10, comprising at least one of the following features:
wherein the method comprises treating the release layer and/or the encapsulant, in particular by supplying heat, for promoting release of the encapsulated chip sections from the release layer;
wherein the method comprises collecting the encapsulated chip sections released automatically, in particular falling down by the force of gravity, from the release layer;
wherein the method comprises releasing all encapsulated chip sections in a common process under the force of gravity and by reducing an attaching force of the release layer, in particular by supplying heat.

12. The method according to claim 1, comprising at least one of the following features:
wherein the encapsulant comprises a photo imaging polymer;
wherein the method comprises washing away the uncured other portions of the encapsulant apart from the encapsulated chip sections.

13. A package which comprises:
a chip; and
an encapsulant encapsulating part of the chip and comprising a locally cured material and an agent for locally curing said locally cured material.

14. The package according to claim 13, wherein said locally cured material is obtained from locally curing a locally curable material by irradiation with electromagnetic radiation, in particular ultraviolet electromagnetic radiation.

15. The package according to claim 13, wherein said locally cured material comprises a cured polymer, and wherein said agent comprises a photoinitiator, said photoinitiator being configured for promoting curing of an initially uncured polymer to thereby form said cured polymer when being irradiated with electromagnetic radiation, in particular ultraviolet electromagnetic radiation.

16. The package according to claim 13, wherein said encapsulant comprises a photo imaging polymer.

17. The package according to claim 13, wherein said encapsulant encapsulates sidewalls and only one main surface of the chip.

18. The package according to claim 17, wherein a thickness (D) of said encapsulant on at least part of the sidewalls is in a range from 10 μm to 75 μm.

19. The package according to claim 13, wherein the chip comprises at least one of the group consisting of a diode chip, and a passive electronic component.

20. The package according to claim 13, wherein the chip comprises at least one pad exposed at a main surface of the chip which is exposed with respect to the encapsulant.
